(19) United States
(12) Patent Application Publication
(10) Pub. No.: US 2015/0325404 A1
(43) Pub. Date: Nov. 12, 2015

(54) LITHOGRAPHY APPARATUS AND METHOD, AND METHOD OF MANUFACTURING AN ARTICLE

(71) Applicant: CANON KABUSHIKI KAISHA, Tokyo (JP)

(72) Inventors: Yusuke Sugiyama, Kawasaki-shi (JP); Satoru Oishi, Utsunomiya-shi (JP); Hideki Ina, Tokyo (JP); Shigeki Ogawa, Utsunomiya-shi (JP)

(21) Appl. No.: 14/703,976

(22) Filed: May 5, 2015

(30) Foreign Application Priority Data
May 9, 2014 (JP) 2014-098050

(51) Int. Cl. H01J 37/147; H01J 37/304

(52) U.S. Cl. CPC H01J 37/1471; H01J 37/304; H01J 2237/15; H01J 2237/31723; H01J 2237/063

(57) ABSTRACT

A lithography apparatus for performing patterning on a substrate with a charged particle beam is provided. An optical system of the apparatus has a function of adjusting the focus position of the charged particle beam and the irradiation position of the charged particle beam on the substrate, and irradiates the substrate with the charged particle beam. A controller of the apparatus controls the optical system such that the patterning is performed with adjustment, of the focus position and the irradiation position based on the surface shape of the substrate for adjustment of the focus position, accompanied with the patterning.

### BACKGROUND OF THE INVENTION

1. Field of the Invention

The present invention relates to lithography technology in which patterning is performed on a substrate with a charged particle beam.

2. Description of the Related Art

With conventional charged particle beam drawing (exposing) apparatuses for forming a pattern (latent pattern) on a substrate, patterning is performed on a substrate by, for example, shaping and demagnifying an electron beam emitted from an electron gun, and irradiating the substrate with the electron beam. This kind of patterning can be performed by beam modulation and scanning the stage holding the substrate. An electron beam drawing apparatus is advantageous in terms of having excellent resolving power.

In the drawing apparatus of Japanese Patent Laid-Open No. 2009-70945, in order to achieve superposition performance, the deflector for changing the position of the electron beam on the substrate (the deflector that deflects the electron beam) is included in the electron optical system of the drawing apparatus.

The electron optical system described in Proc. SPIE 2522, Electron-Beam Sources and Charged-Particle Optics, 66 (Sep. 25, 1995) has a so-called dynamic focus function, which is a function for correcting (adjusting) the focus of the electron beam. In the case where the electron beam from the electron optical system is not perpendicularly incident on the substrate (in the case of telecentric error), if focus correction is performed as shown in FIG. 8, not only the focus state of the beam changes, but also the irradiation position of the beam on the substrate changes. For this reason, the change in the irradiation position is compensated for by a deflector operation in Japanese Patent Laid-Open No. 2009-70945.

Also, a configuration in which multiple electron optical systems are provided together (also called a multicolumn configuration) has been proposed (U.S. Pat. No. 7,897,942) in order to improve the throughput of drawing apparatuses. In the configuration disclosed in U.S. Pat. No. 7,897,942, 36 electron optical systems are provided together.

In the multicolumn configuration, when the substrate is deformed, focus shifts among columns. Thus, in the case of the multicolumn configuration, error in the surface shape of the substrate as shown in FIG. 9A becomes focusing error. Even if the substrate is moved as shown in FIG. 9B to address this, it is difficult to perform appropriate focus adjustment for all of the columns, and thus dynamic focusing is necessary. However, even if dynamic focusing or the deflector as shown in Japanese Patent Laid-Open No. 2009-70945 is applied to the situation shown in FIG. 9B, the beam irradiation position can become shifted as shown in FIG. 9C. This is because Japanese Patent Laid-Open No. 2009-70945 is based on the premise that the surface of the substrate is flat (a flat surface is used as the reference surface in calibration). The inventors of this invention discovered that this new problem related to superposition precision can occur, and although this problem has not occurred conventionally due to leeway in the focal depth of the electron beam, it can occur due to reduction in the focal depth that accompanies the decreasing size of patterns to be drawn.

### SUMMARY OF THE INVENTION

One aspect of the present invention provides, for example, a lithography apparatus that is advantageous in terms of overlay precision.

According to one aspect of the present invention, a lithography apparatus which performs patterning on a substrate with a charged particle beam is provided. The apparatus comprises an optical system having a function of adjusting a focus position of the charged particle beam and an irradiation position of the charged particle beam on the substrate, and configured to irradiate the substrate with the charged particle beam, and a controller configured to control the optical system such that the patterning is performed with adjustment, of the focus position and the irradiation position based on a surface shape of the substrate for adjustment of the focus position, accompanied with the patterning.

Further features of the present invention will become apparent from the following description of exemplary embodiments with reference to the attached drawings.

### BRIEF DESCRIPTION OF THE DRAWINGS

FIG. 1 is a schematic diagram of a multicolumn electron beam exposure apparatus according to an embodiment.

FIG. 2 is a schematic diagram of an electron optical system unit according to the embodiment.

FIG. 3 is a diagram showing an example of a database indicating a relation between correction system driving amounts and electron beam displacement.

FIG. 4 is a diagram for describing processing for determining the irradiation position of an electron beam on a grid.

FIG. 5 is a flowchart for describing correction system adjustment processing according to the embodiment.

FIG. 6 is a flowchart for describing beam position measurement processing according to the embodiment.

FIG. 7 is a flowchart for describing exposure correction processing according to the embodiment.

FIG. 8 is a diagram for describing telecentric error.

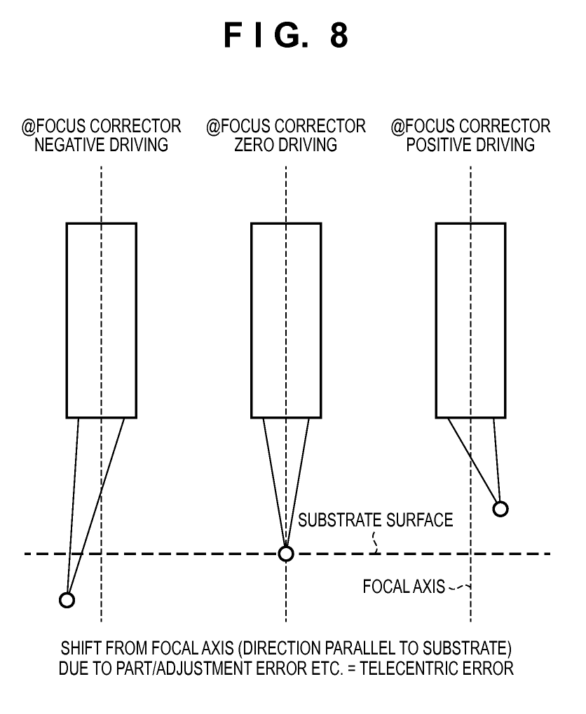

FIGS. 9A to 9C are diagrams for describing problems in conventional technology.

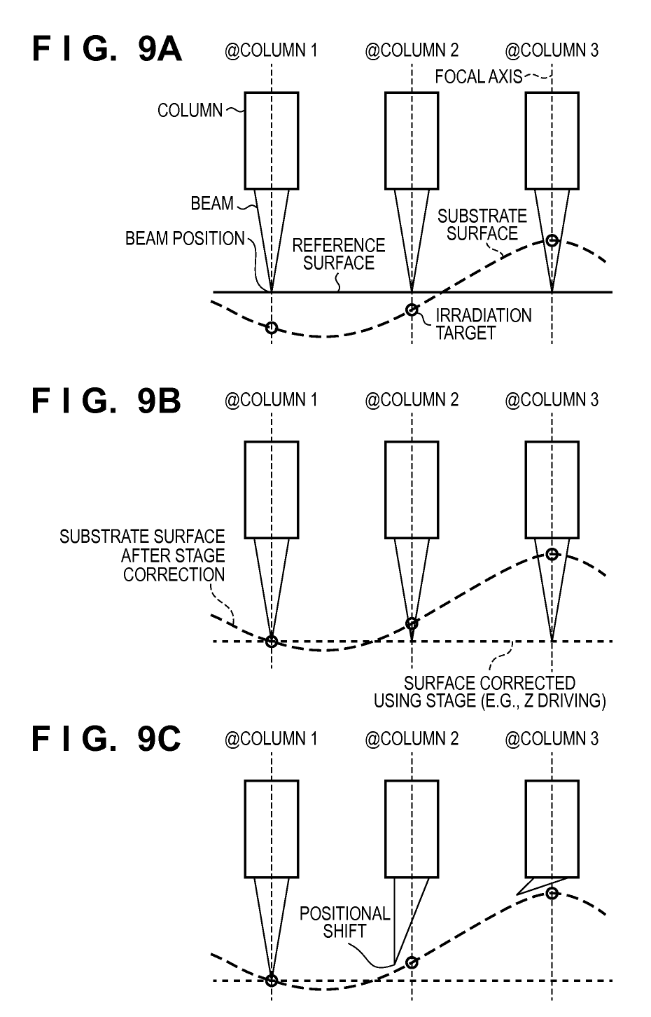

FIGS. 10A to 10C are diagrams for describing the principles of beam position measurement according to the embodiment.

### DESCRIPTION OF THE EMBODIMENTS

Various exemplary embodiments, features, and aspects of the invention will be described in detail below with reference to the drawings.

A preferred embodiment of the present invention will be described in detail below with reference to the drawings. Note that the present invention is not limited to the following embodiment, and the following merely describes a specific example that is advantageous to carrying out the present invention. Also, all combinations of the features described in the following description are not necessarily essential to the solution provided by the present invention.

The following embodiment of the present invention describes an electron beam exposure apparatus that employs an electron beam as one example of a charged particle beam. Note that the present invention is not limited to an electron beam, and is similarly applicable to an exposure apparatus that employs a charged particle beam such as an ion beam.

Apparatus Configuration

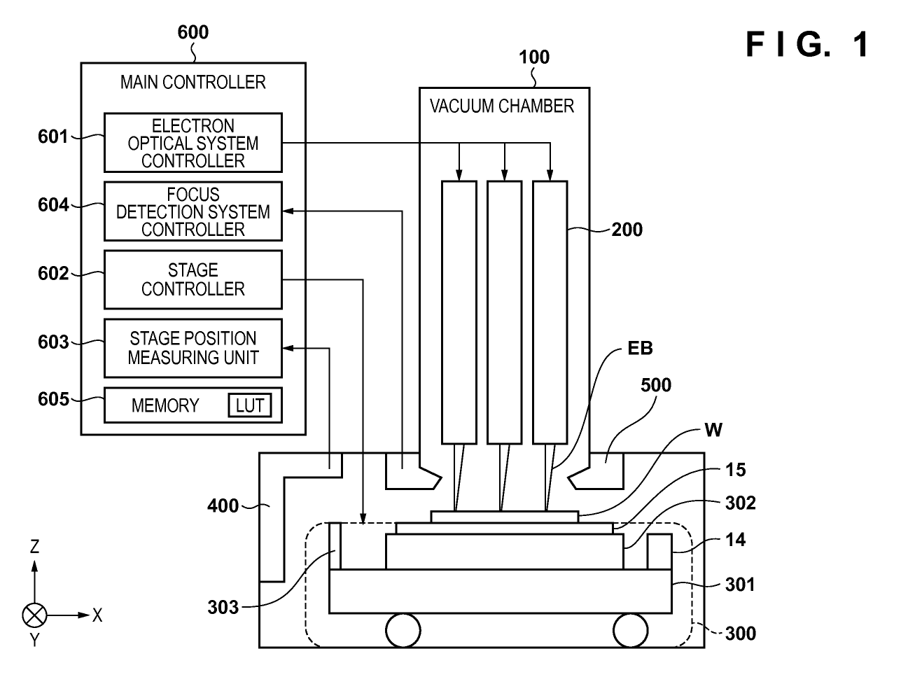

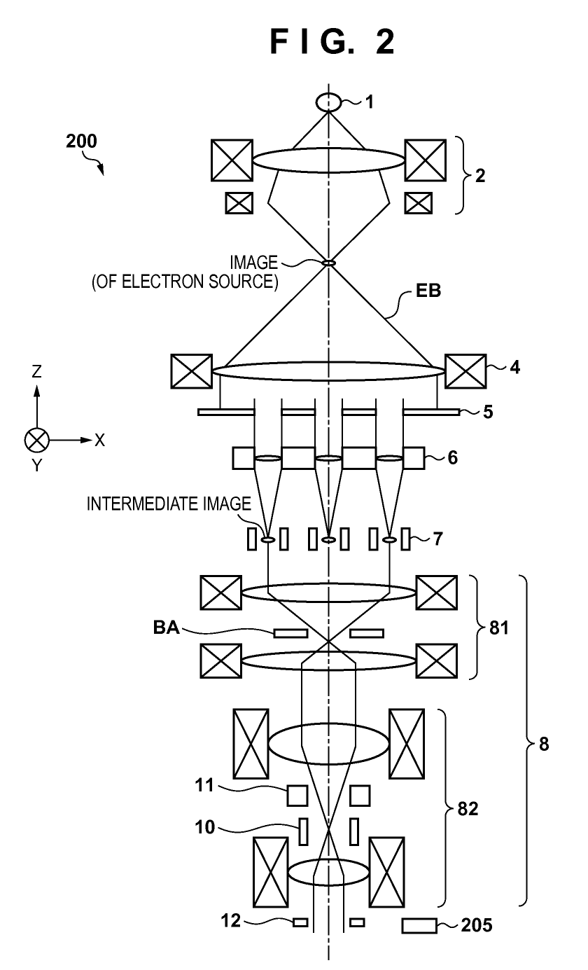

A first embodiment of the present invention will be described below. FIG. 1 is a schematic diagram of relevant portions of an electron beam exposure apparatus serving as a lithography apparatus for performing patterning on a substrate. FIG. 2 is a diagram showing details of an electron optical system unit 200 shown in FIG. 1. A multicolumn multibeam raster scan type of electron beam exposure apparatus is used in this case in particular. A feature of this type of exposure apparatus is that an electron beam emitted from one electron gun is divided into multiple beams, and the electron beams are repeatedly scanned in one direction over the entire surface of a drawing area in an angle of view in order to form a pattern on a substrate.

FIG. 1 is a diagram showing the main configuration of the electron beam exposure apparatus of the present embodiment. An electron optical system unit 200, a stage 300, a stage position measuring system 400, a focus detection system 500, and the like are arranged in a vacuum chamber 100 that has been evacuated by a vacuum pump (not shown).

The following describes the configuration of the electron optical system unit 200 with reference to FIG. 2. An electron beam emitted from an electron source 1 passes through an optical system 2 for shaping the beam shape of the electron beam, and forms an image of the electron source 1. A collimator lens 4 forms an approximately parallel electron beam from the electron beam from the image. The approximately parallel electron beam then passes through an aperture array 5. The aperture array 5 has multiple openings and divides the electron beam into multiple electron beams. The divided electron beams obtained by the aperture array 5 form intermediate images of the image of the electron source 1 due to an electrostatic lens array 6 in which multiple electrostatic lenses are formed. A blanker array 7, in which multiple blankers (electrostatic deflectors) are formed, is arranged at the intermediate image plane.

A charged particle optical system 8 constituted by symmetric magnetic doublet lenses 81 and 82 at two levels is arranged downstream of the intermediate image plane, and the intermediate images are projected onto a substrate W such as a wafer. The charged particle optical system 8 has a Z-direction axis, and emits multiple electron beams onto the substrate. The Z direction is the direction parallel to the axis of the charged particle optical system 8. The electron beams deflected by the blanker array 7 are blocked by a blanking aperture BA, and thus are not incident on the substrate W. On the other hand, the electron beams not deflected by the blanker array 7 are not blocked by the blanking aperture BA, and thus are incident on the substrate W. A deflector 10 for displacing multiple electron beams toward drawing positions that are targets in the X and Y directions at the same time, and a focusing coil 12 for adjusting the focus of multiple electron beams at the same time are arranged in the lower doublet lens 82. In the following, the focusing coil 12 has a function of dynamically correcting the focus position during drawing as well, and will also be referred to as dynamic focuser or a focus corrector. Also, the measurement of the shape of the electron beams at positions in the irradiation plane of the substrate W is performed by a detector 14 that includes a knife-edge. A stigmator 11 adjusts astigmatism of the charged particle optical system 8. Also, an electron detector 205 detects reflected electrons that appear when the substrate W is irradiated with an electron beam EB, and obtains an electron image of the substrate W by processing the detection result. These constituent elements are controlled by an electron optical system controller 601.

The stage 300 has a stage surface plate 301 that has a reference surface, and a stage driving system 302, which moves the substrate W being held by an electrostatic chuck 15, and a length measurement member 303 that are arranged on the stage surface plate 301. The stage driving system 302 is capable of translation movement along the X axis and Y axis, which are directions in the stage plane, and along the Z axis, which is the direction perpendicular to the stage plane, and also rotation movement relative to these axes. A stage controller 602 controls positioning in six degrees of freedom in these movements, and thus the substrate W can be moved to a desired position.

The stage position measuring system 400 detects an intensity signal of interfering light that is generated when a laser emitted from an internally provided laser light source is reflected back by the length measurement member 303 (e.g., a bar mirror). The detected intensity signal is then processed by a stage position measuring unit 603, and thus the position of the stage is measured.

In the case of using a triangulation measurement principle, the focus detection system 500 irradiates the substrate W with oblique incidence focus measurement light, receives reflected light, and performs signal processing with a focus detection system controller 604, and thus detects the position of the substrate W in the Z direction.

A main controller 600 is a control system that processes data from the electron optical system controller 601, the stage controller 602, the stage position measuring unit 603, and the focus detection system controller 604 that are described above, and gives instructions to these controllers, for example. Also, a memory 605 is a storage unit that stores information needed by the main controller 600. For example, the memory 605 stores information on the relation that adjustment amounts related to adjustment of the focus position and the irradiation position have with corresponding adjustment results.

Coordinate System

The following describes a coordinate system. The positional relation between the stage position measuring system and the reference surface of the stage 300 is set in advance, and other coordinate systems are determined based on this relationship. As previously described, there is the X axis, which is a direction in the stage plane, the Y axis, which is the direction perpendicular to the X axis in the stage plane, and the Z axis, which is the direction perpendicular to the substrate plane. In terms of design, the electron beam reference position is the position at which the electron beam EB from the electron optical system unit 200 is incident on the stage when not deflected by the deflector 10. Also, the stage position measuring unit 603 is set in advance such that the reference position is detected as the center of the stage. With respect to the reference position, the X axis and Y axis directions are electron optical system shift directions, and the Z axis direction is the focus direction. Note that the relative position of the reference position of the electron optical system relative to the reference position of the focus detection system 500 is also known in advance. Also, a predetermined range exposed by one electron beam during scanning by the deflector is called the field. In terms of design, this field is a grid-like region extending two-dimensionally in the in-plane directions centered about the reference position, and the grid points correspond to the pixels of the pattern that is to be exposed, at a predetermined ratio. Normally, drawing is performed by irradiating the substrate with the electron beam at these grid points.

Correction System Adjustment Method

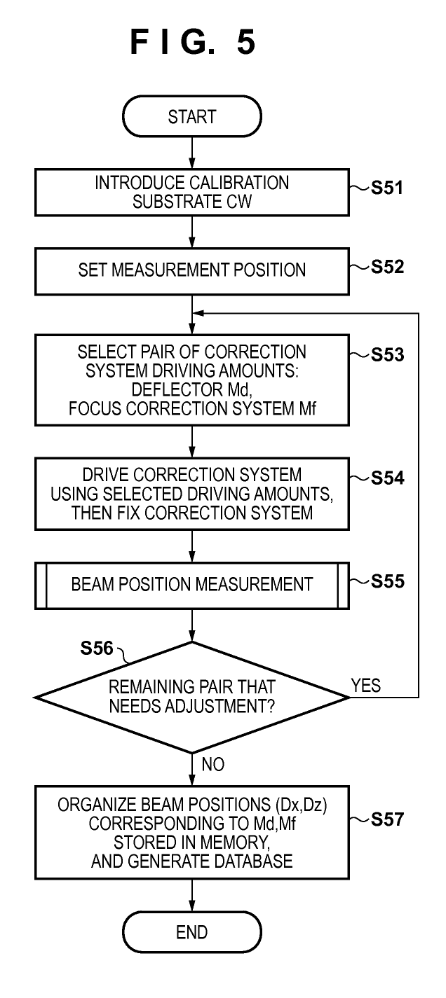

Next, the correction system used when correcting the irradiation position of the electron beam EB, that is to say the method for adjusting the deflector 10 and the focusing coil 12, which is the focus corrector, will be described with reference to the flowchart in FIG. 5. In order to facilitate understanding in the following description, only the X axis is used as the direction in the substrate plane, and X-Z coordinates are used. The deflector is normally deployed with the ability to achieve movement in both the X axis and the Y axis, but the following description limits the axes of movement to only the X axis.

First, a calibration substrate CW is placed on the stage (step S51). The calibration substrate is provided with at least one or more cross marks, for example. Thereafter, the stage is moved such that the center of the calibration substrate or the center of the mark serving as the measurement reference is located at the reference position of the electron optical system (step S52). Alternatively, it is sufficient to obtain correspondence between the reference position of the electron optical system, and the mark center and stage position.

Although not shown, it is desirable that the correction system correction amounts (driving amounts) are initialized (e.g., the deflection voltage is set to 0) before adjustment of the correction system is started. Confirming initialization before performing adjustment makes it possible to diagnose whether or not the electron beam is stable, whether or not the correction amounts are to be initialized after adjustment, and the like. In this state, the electron beam is incident on the reference position of the electron optical system.

Subsequently, information is acquired on the correspondence relation between the correction amounts of the correction system and displacement of the electron beam that accompanies correction of the correction system. In order to acquire this information, the amount of displacement of the irradiation position of the electron beam from the reference position is measured in the case where the correction amounts of the correction system are fixed at a certain pair. The variables shown in FIG. 5 will be defined below. Md is the driving amount of the deflector, Mf is the driving amount of the focus corrector, and D(Dx,Dz) is the displacement from the reference position of the electron beam.

Pairs of correction system driving amounts (also called adjustment values in adjustment) are determined based on a predetermined range and interval. It is desirable that the range is determined so as to slightly exceed the field, and the interval is determined to be sufficiently small in accordance with the required precision. One set is selected out of these pairs of driving amounts (step S53). In this description, it is assumed that the range is −Rd<=Md<=Rd, and the interval is Sd. Here, assume that in the selected pair, Md=Sd for the deflector, and Mf=0 for the focus corrector.

After the pair of driving amounts for the focus corrector and the deflector is selected, the correction system is driven according to these driving amounts, and the state of the correction system and the position of the electron beam are fixed (step S54). Thereafter, the irradiation position of the electron beam is measured (step S55) (this processing is called electron beam “beam position measurement”). As a result of the beam position measurement, (Dxi,Dzi) is accumulated in the memory as the beam position that corresponds to the current correction system driving amounts (Md=Sd,Mf=0). When the beam position measurement ends, it is checked whether there are any remaining pairs of driving amounts for which adjustment has not been performed (step S56), and if any remain, the next pair (e.g., Md=2Sd,Mf=0) is selected, and similar processing is repeated.

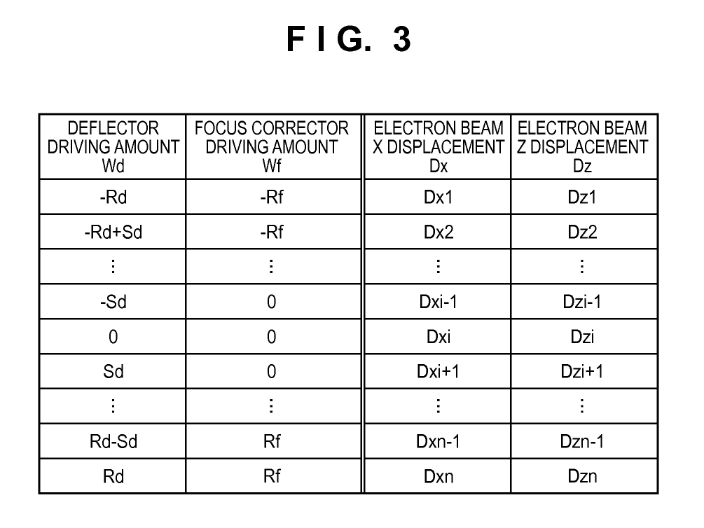

If no pairs remain, the data accumulated in the memory due to the beam position measurement is organized and converted into a database in a format for use in later exposure processing (step S57). For example, table-formatted data is generated as shown in FIG. 3. In this way, by measuring the position of the electron beam for each predetermined pair of driving amounts for the deflector and the focus corrector, the main controller can acquire the correspondence relation between the correction system driving amounts and displacement of the electron beam that accompanies the driving of the correction system. In the conversion into a database, it is sufficient to obtain a format in which corrector driving amounts are output when an electron beam target position is given, for example. For example, a look-up table LUT may be held in the memory 605 as shown in FIG. 1. Also, electron beam irradiation positions not corresponding to the predetermined pairs from which the table was created can be obtained by data interpolation. Moreover, instead of using a look-up table format, a function may be obtained based on beam position measurement. When adjustment of the correction system is complete, the calibration substrate is carried away from the stage.

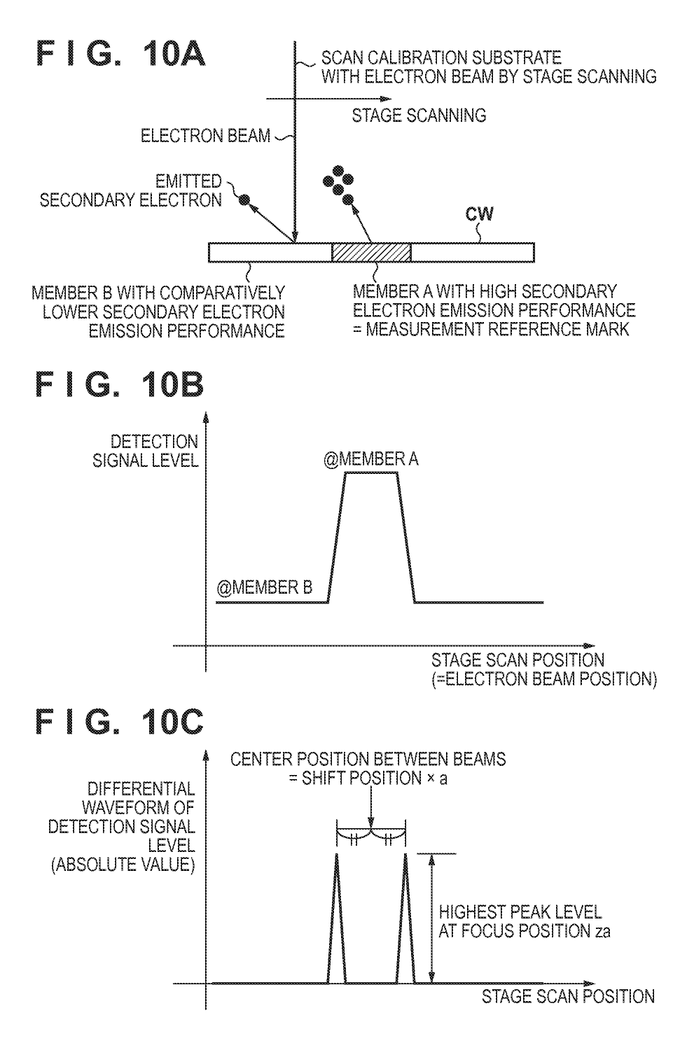

Next, the measurement principle used in beam position measurement will be described with reference to FIGS. 10A to 10C. As shown in FIG. 10A, in beam position measurement, the substrate is scanned with the electron beam by emitting the electron beam while scanning the stage in the X direction. At this time, electrons emitted from the substrate are detected by the electron detection system (electron detector 205). Since members with different secondary electron emission characteristics are formed in front of and behind the mark on the substrate, different numbers of electrons are detected. As a result, different signal levels are detected as shown in FIG. 10B, and a shape on the measurement surface is obtained as an electron image. Also, since the correspondence between the position of the electron detection system and the stage position is known, which stage position grid point the mark center position corresponds to is known.

FIG. 10C shows a waveform (absolute values) obtained by differentiation of the waveform shown in FIG. 10B. Peaks appear at the edges of the mark. Also, it is known that in electron microscope technology, as the focus state of the electron beam improves, the emission of secondary electrons increases, and thus the peak becomes sharper. Based on this, it is possible to measure the positions at which the peak is highest as the in-focus positions, and measure the center between these measured peaks as the mark center position, that is to say the beam shift position.

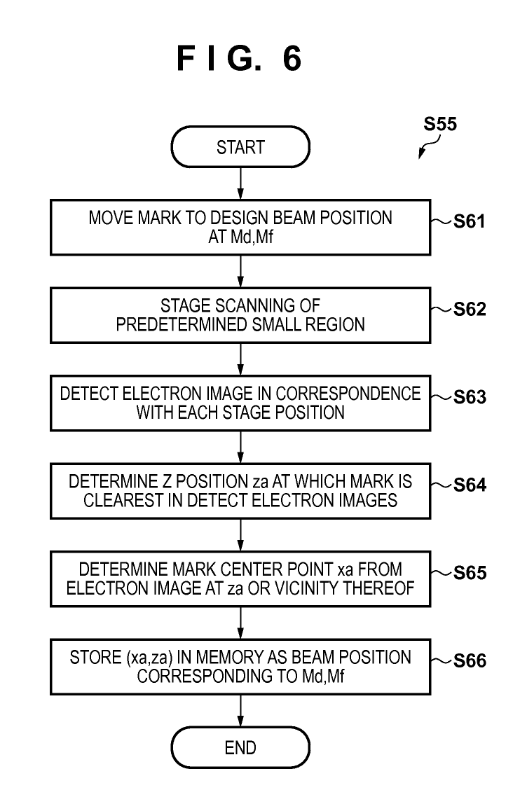

The following describes one example of a method for beam position measurement shown in step S55 in FIG. 5, with reference to the flowchart in FIG. 6. The mark is moved to the design beam position that corresponds to the correction system driving amounts set before starting position measurement (step S61). Small regions in the vicinity of the design beam position are scanned on the stage (step S62), and electron images (detection signals) corresponding to the scan positions are acquired (step S63). The small regions referred to here are ranges that encompass shift from the envisioned design beam position, and are specifically three dimensional spaces corresponding to several grid points at the most, for example. Also, the interiors of the small regions are densely partitioned according to the stage position measuring precision and the measurement resolution of the electron detection system.

As previously described, first, the focus position Dz is determined as za (step S64). In this case, peak signal levels are obtained while successively driving the stage in the Z direction, but a configuration is possible in which electron images are successively acquired at a certain interval, and analysis is performed after acquisition. Also, the best focus position may be obtained by estimating, based on the data, the position at which the peak signal level takes the highest value. Note that this processing may be skipped if shift from the design value in the focus direction can be ignored. Next, the shift position Dx is determined as xa (step S65). In this case as well, it is sufficient to find the position of the center between the peaks as previously described. The electron images used in analysis at this time is not limited to electron images at the best focus position, and it is possible to clearly find the position of the center anywhere in the vicinity of the best focus position. Also, the position of the center may be estimated from multiple electron images similarly to the focus position determination. The analysis method used here is to be selected in accordance with the precision required in beam position measurement. The beam position (xa,za) that corresponds to the set correction system driving amounts (Md,Mf) set in this way is stored in the memory (step S66).

Focus Shift in the Correction System During Deflector Driving

By performing adjustment as described above, the correction system is strictly managed in a substantially three-dimensional (only X-Z coordinates in this example) space. According to this adjustment method, it is possible to measure shift that occurs in the focus direction as well when driving the deflector. Step S64 in FIG. 6 is processing for measuring this focus shift. A feature of the electron beam is that some extent of focus shift is allowable due to the deep focal depth of the electron beam. For this reason, the processing of step S64, which is for managing focus shift, may be skipped depending on the pattern that is to be exposed and the state of surface deformation of the substrate.

Method of Acquiring Substrate Surface Shape

An exposure target substrate W is placed on the stage, and the focus detection system 500 emits focus measurement light toward the substrate W and receives detection light that was reflected by the substrate W. The detected light is subjected to photoelectric conversion, signal processing is performed by the focus detection system controller 604, and the focus position of the substrate W is measured in the Z direction here. This is repeated while moving the substrate W in the X and Y directions, and it is possible to obtain surface shape information (also called a focus map) for the entire surface of the substrate W.

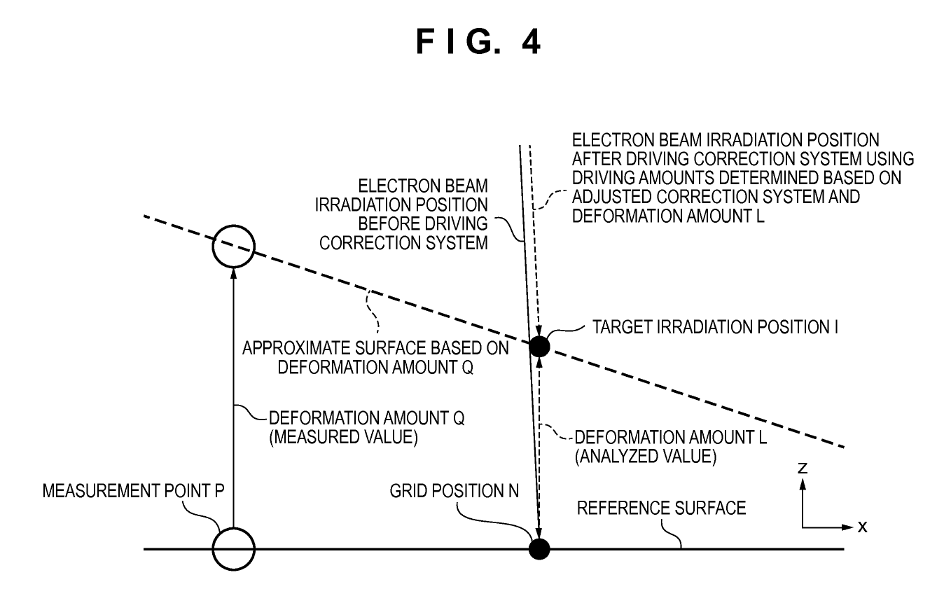

As a result of this measurement, a deformation amount Q (Qz) is obtained at the measurement position P (Px) on the substrate W as shown in FIG. 4. Since the state of deformation of the substrate W compared to the design surface shape is known, the position of the electron beam can be corrected in later exposure correction such that the pattern is exposed at positions conforming to the deformation.

Telecentric Error

The following describes the case where the electron beam does not perpendicularly irradiate the wafer being drawn on. In terms of optics, “telecentric” refers to the position of the pupil in an image forming relation with the diaphragm being at infinity, and this is understood to mean that the main light beam is perpendicular to the wafer (is parallel with the optical axis) at each angle of view. However, this is an approximate definition and not correct in a strict sense (note that this approximate definition is the same for pure optics and for electron beam image forming). If the image forming relation (strictly speaking, pupil image forming) has aberration, the wafer will be irradiated with the electron beam at an angle that is somewhat shifted from perpendicular at each angle of view. This is determined by a design value. On the other hand, the wafer is irradiated with the electron beam at an angle that is somewhat shifted from perpendicular at each angle of view due to parts error and adjustment error as well, not the design value.

In this specification, all of the small extent of shift from perpendicular on the wafer is called “telecentric error”. For the above-described reasons, “telecentric error” generally takes different values at various angles of view. In other words, in the case of performing the above-described dynamic focusing, it needs to be considered that “telecentric error” changes. Accordingly, in the present embodiment, “telecentric error” in various cases of performing dynamic focusing is measured in advance, saved in a database or the like, and then made use of.

Exposure Correction Method

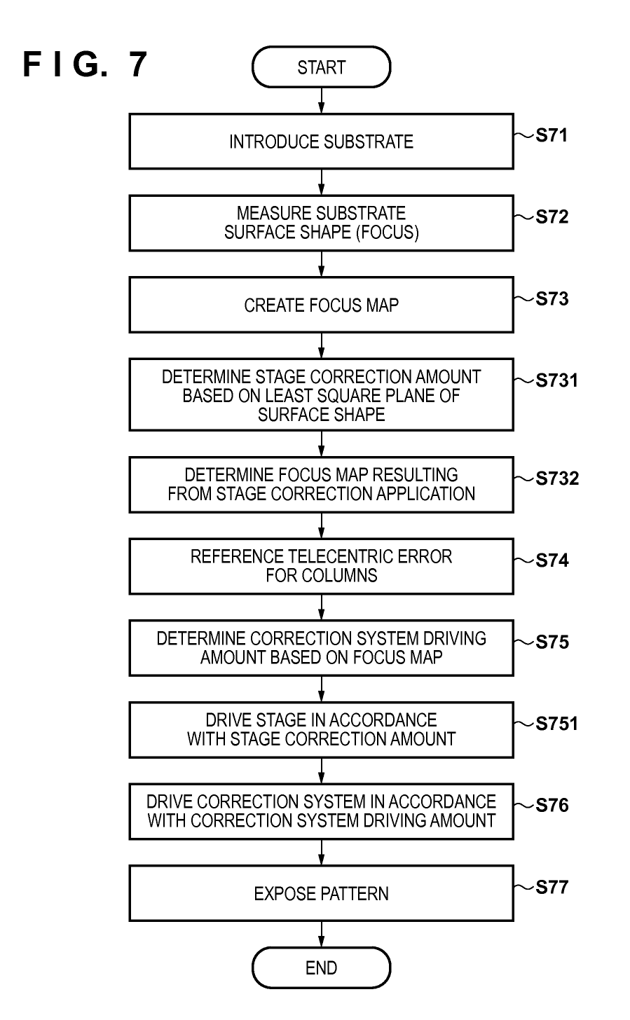

Pattern exposure is performed based on the measured substrate deformation amount Q, using the adjusted correction system. FIG. 4 shows the process of exposure correction, FIG. 7 shows a flowchart of exposure, and the following description is given with reference to these figures. The exposure target substrate W is introduced to the stage (step S71), and then, firstly, focus measurement is performed using the focus detection system 500 in order to obtain the surface shape of the substrate (step S72). This measurement is performed as described in the section “Method for acquiring substrate surface shape” above. The focus detection system controller 604 then performs analysis processing on the measurement signal, and obtains a focus map (step S73). In FIG. 4, the deformation amount Q is shown for measurement points P indicated by large circles aligned at a predetermined interval. Since this corresponds to a distance in the focus direction, Qz can be used. The focus map is analyzed, and the surface shape of the substrate is obtained by approximation by a least-square method, for example, thus obtaining the approximate surface indicated by a dashed line extending obliquely in FIG. 4.

After this, if a portion of the correction of the beam position with respect to the surface shape is to be corrected by stage driving, the processing of steps S731 and S732 is added. The planar component (translation and rotation) of the approximate surface obtained in the previous processing is determined as the stage correction amount (step S731). Next, the deformation amount of the surface shape to be corrected by the stage correction amount is subtracted from the deformation amount before the application of correction, and a focus map (or approximate surface) that gives consideration to stage correction is generated again (step S732).

Before determining the correction system driving amount, telecentric error for columns obtained in advance in adjustment processing is read out (step S74). In other words, it is made possible to reference the database DB generated in adjustment processing.

Next, the driving system correction amount is determined (step S75). Based on the measured deformation amount Q of the substrate W and the generated focus map, a deformation amount L(Lx,Lz) that corresponds to the field grid position N(Nx) is calculated. Note that as shown in FIG. 4, the field grid position N and the measurement position P on the substrate W are not necessarily the same position and alignment. In view of this, the deformation amount L at the grid position N is obtained based on the approximate surface previously obtained based on the focus map. Note that instead of being obtained based on the approximate surface, the deformation amount L may be obtained by interpolation based on deformation amounts Q at measurement points P in the vicinity, for example. Although the deformation amount L is shown as the focus Z direction in FIG. 4, there are also cases of having a component in the shift direction depending on the deformation amount that is acquired, stage correction, and the like.

An electron beam irradiation position I(Ix,Iz) is determined according to the obtained deformation amount L. Specifically, when the deformation amount L is added to the grid position N, then Ix=Nx+Lx, Iz=Lz. Note that if the correction system of the electron optical system independently performs correction for cases other than exposure on a predetermined grid, a configuration is possible in which only the deformation amount L is distributed to the correction system when determining the electron beam irradiation position.

A position separated from the grid position N by the deformation amount L is, in other words, nothing other than the irradiation position I that is the electron beam target. Accordingly, it is sufficient to determine the correction system driving amount that corresponds to the irradiation position I.

If the correction system driving amount that corresponds to the determined electron beam irradiation position is input as a parameter to the database DB indicating the relation between the correction system driving amount and the electron beam displacement, the corresponding correction system driving amount M(Md,Mf) is output. Note that the generated database DB and the irradiation position I do not necessarily match. In view of this, an appropriate driving amount M is determined by the least-square method, for example. In other words, a search is performed to find a pair displacement amounts in the database that obtains the lowest sum of the square of the difference between the displacement amounts and the target irradiation position for each axis. Alternatively, if the database is not dense, a detailed database may be created by interpolation in advance.

After the correction system driving amount is determined, the stage is moved such that the substrate W is positioned in the field that has the pattern that is to be exposed. Furthermore, in the case of performing stage correction, the stage is driven in accordance with the previously determined stage correction amount (step S751). If stage correction is not to be performed, the correction amount is 0. The deflector and the focus corrector are driven in accordance with the determined correction system correction amount (step S76).

The above processing achieves preparation for performing electron beam position correction so as to accommodate the deformation of the surface shape of the substrate. As a result, the electron beam irradiation position indicated by the solid line in FIG. 4 is moved by the correction system to the position indicated by the dashed line in the figure, and the pattern can be exposed at the target irradiation position.

After preparation is complete, the substrate W is irradiated with the electron beam based on the pattern data (step S77). When exposure in the field ends, the stage is moved to the next field, and exposure is performed in a similar manner. Note that a configuration is possible in which the stage is scanned in a constant manner, and the deflector is aligned so as to track the scanning in the scanning direction. When exposure of the entire pattern ends, the substrate W is carried away, and exposure is completed. In this way, the main controller controls correction by the correction system in synchronization with the progress of drawing with the electron beam on the substrate W.

The following describes an example in which the calculation of the deformation amount for a grid position and the determination of the correction system driving amount are performed during exposure processing. However, the measurement data and pattern data of the electron beam exposure apparatus generally have large data sizes. In view of this, these processes may be performed offline in advance (prior to exposure).

Although the deflector and the focus corrector are treated as the correction system in the present embodiment, an astigmatism corrector may be added, and a configuration with multiple stages is also possible. In this case, it is sufficient to adjust the various mechanisms separately in the adjustment method of this description.

Focus Map and Deflection Correction

If the flatness of the substrate does not have very much error that is high in terms of spatial frequency, the measurement sampling in the substrate W in the focus map can be a rough number, such as a pitch of several mm for example, and it is possible to prevent throughput reduction due to this measurement.

In this case, if the grid in deflection correction has a smaller pitch, the focus shift amount at grid points need only be interpolated from the focus map. In this case, it is effective to perform processing in which four focus map data pieces that are close to the grid points are used, weighting is performed on the inverse of several powers of the XY plane difference, and the focus map that is to be used is obtained.

Also, if a high fraction of the measurement pitch of the focus map is used as the tolerance, and the difference in the XY direction of the four focus map data pieces close to the grid points is small, the data for only one focus map is used. This makes it possible to avoid division by zero.

Also, although the focus map is stored as a database, the following describes the case where there is concern that the reading out of data will be time-consuming. In the case of a multicolumn apparatus, which drawing is to be performed is known in advance. Accordingly, if there is concern that the reading out of data will be time-consuming, a configuration is effective in which the focus map is switched accordingly, and only the necessary data is read out.

Multicolumn

In order to improve the productivity of the electron beam exposure apparatus, there is a multibeam apparatus in which multiple electron beams are generated from one electron gun and used in exposure, and a multicolumn apparatus that includes multiple columns that each include an electron optical system and a correction system. When the present invention is applied to a multicolumn electron beam exposure apparatus for example, particularly significant effects can be expected as described below.

With a single column apparatus that has only one electron optical system, irradiation position correction can be substituted by linking with position correction using the stage. However, this substitution method not only requires high precision in stage control, but also forces high-load operation, and therefore is not desirable.

With a multicolumn electron beam exposure apparatus, the pattern needs to be exposed at multiple mutually different positions on a single substrate at the same time. Similarly to the single column apparatus, even if an attempt is made to substitute irradiation position correction in stage control, by merely controlling one plane with the stage, it is not possible to control points away from that plane. Accordingly, it is not possible to use the substitution method that is used in the case of a single column apparatus.

In contrast, in the present embodiment, it is possible to adjust the displacement amount of the electron beam and the driving amount of the correction system for each column. Accordingly, the electron beam irradiation position in each column can be corrected in accordance with the surface deformation of the substrate at the respective column positions.

Also, by compensating for components that are common to all columns (translation and rotation) through stage control, it is possible to suppress the total driving amount distributed in correction system in the respective columns to a low value. Accordingly, the dynamic range obtained in the correction system is suppressed to a smaller range, and therefore it is possible to expect higher precision and power saving in the correction system, and a lower footprint.

Application to Single Column Apparatus

Even if the dynamic focusing of the present invention is used while performing correction, instead of using a conventional method of correcting focus shift by moving the wafer in the Z direction, pattern superposition is possible in a configuration and processing method similar to those described above. This is effective in the case where, for example, the drawing scanning is fast, and the configuration is not capable of handling that speed with Z driving.

Note that if the amount of shift of substrate focus is greater than the largest amount of driving in dynamic focusing, the wafer needs to be moved in the Z direction. The same applies in the case of a multicolumn apparatus as well, and it is preferable that driving is performed not only in the Z direction, but with respect to tilt as well, and focusing is performed to reduce the amount of focus shift in each column. For example, it is sufficient to move the stage so as to minimize the sum of squares of the shift amount. Of course, if the amount of focus shift in columns is smaller than the largest adjustment amount in dynamic focusing, it is not necessarily required to perform wafer tilt driving and Z driving at each position in wafer scanning.

Deflection Amount Correction Items

A lithography drawing method employing an electron beam has a merit of not using a mask and a reticle, and thus is also called ML2. Additionally, as a drawing method, there is also a merit in that if information for correction in order to draw a desired drawing pattern by deflecting an electron beam is known, superposition performance is improved by changing the deflection amount when performing drawing.

For example, the wafer pattern that drew the previous layer in a light exposure apparatus has distortion aberration component shift remaining in the projection optical system of the light exposure apparatus. If this shift component is measured in advance using a superposition examination apparatus or the like, in the ML2 drawing apparatus, by correcting the electron beam deflection amount, it is possible to prevent degradation of precision in superposition performance caused by the distortion aberration component remaining in the projection optical system of the light exposure apparatus.

Also, according to U.S. Pat. No. 7,897,942, heat is generated when the electron beam is incident on the wafer, and the wafer becomes elongated due to this influence. In this case as well, it is possible to prevent degradation in the precision of superposition performance by measuring the amount of elongation or the like during drawing, and correcting the electron beam deflection amount based on that information.

With a method of performing drawing by scanning a wafer, the driving precision of the wafer stage that scans the wafer influences the drawing precision. In this case as well, if the stage position is measured with high precision by a laser interferometer or the like, even if shift occurs in the driving amount, it is possible to prevent performance degradation by commensurately changing the electron beam deflection amount when performing drawing.

Next, a method of changing the deflection amount when performing drawing with respect to the wafer global alignment result as well will be described. Shift, magnification, and rotation components in the global alignment result of currently-used light exposure apparatuses is dealt with by correcting the wafer driving position in each drawing shot when performing drawing. However, in the case of a multicolumn multibeam ML2 drawing apparatus, even if the magnification and rotation components are dealt with by correcting the wafer position, it is possible for correction to be successful in one column, but result in shift in another column. For this reason, it is not possible to deal with the problem by wafer position correction as with a light exposure apparatus (shifting is possible). In view of this, a method is used in which the magnification and rotation components in the columns are dealt with by changing the electron beam deflection amount when performing drawing.

Embodiment of Method of Manufacturing an Article

A method of manufacturing an article according to an embodiment of the present invention is favorable in, for example, manufacturing articles such as microdevices (e.g., semiconductor devices) and elements having a fine structure. The method of manufacturing an article of the present embodiment includes a step of forming a latent pattern in a photosensitizer applied to substrate, using the above-described drawing apparatus (step of perform drawing on a substrate), and a step of developing the substrate on which the latent pattern was formed in the previous step. Furthermore, this manufacturing method includes other known steps (e.g., oxidation, film formation, vapor deposition, doping, planarization, etching, resist peeling, dicing, bonding, and packaging). The method of manufacturing an article of the present embodiment is advantageous over conventional methods in at least one of article performance, quality, productivity, and production cost.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2014-098050, filed May 9, 2014, which is hereby incorporated by reference herein in its entirety.

What is claimed is:

1. A lithography apparatus which performs patterning on a substrate with a charged particle beam, the apparatus comprising:
an optical system having a function of adjusting a focus position of the charged particle beam and an irradiation position of the charged particle beam on the substrate, and configured to irradiate the substrate with the charged particle beam; and
a controller configured to control the optical system such that the patterning is performed with adjustment, of the focus position and the irradiation position based on a surface shape of the substrate for adjustment of the focus position, accompanied with the patterning.

2. The apparatus according to claim 1, wherein the controller is configured to control the optical system based on the focus position and the irradiation position obtained, as target, based the surface shape of the substrate.

3. The apparatus according to claim 1, wherein the apparatus comprises a plurality of the optical system,
the controller is configured to control each of the plurality of the optical system based on the surface shape.

4. The apparatus according to claim 1, further comprising a storage configured to store information indicating a relation between an adjustment amount of the adjusting and an adjustment result corresponding thereto,
wherein the controller is configured to control the optical system based on the surface shape and the information.

5. The apparatus according to claim 4, wherein the controller is configured to obtain the information by measuring the focus position and the irradiation position with respect to a combination of adjustment amounts of the focus position and the irradiation position.

6. The apparatus according to claim 4, wherein the information is stored in the storage as a look-up table.

7. The apparatus according to claim 6, wherein the controller is configured to obtain a combination of the adjustment amounts, different from the combination in the look-up table, by interpolation of data in the look-up table.

8. The lithography apparatus according to claim 4, wherein the storage stores the information as a function indicating the relation.

9. A lithography method of performing patterning on a substrate with a charged particle beam, the method comprising steps of:
measuring a surface shape of the substrate for adjustment of a focus position of the charged particle beam; and
performing the patterning with adjustment, of the focus position and the irradiation position based on a surface shape of the substrate for adjustment of the focus position, accompanied with the patterning.

10. A method of manufacturing an article, the method comprising steps of:
performing patterning on a substrate using a lithography apparatus; and
processing the substrate, on which the patterning has been performed, to manufacture the article,
wherein the lithography apparatus performs the patterning on the substrate with a charged particle beam, and includes;
an optical system having a function of adjusting a focus position of the charged particle beam and an irradiation position of the charged particle beam on the substrate, and configured to irradiate the substrate with the charged particle beam; and
a controller configured to control the optical system such that the patterning is performed with adjustment, of the focus position and the irradiation position based on a surface shape of the substrate for adjustment of the focus position, accompanied with the patterning.
